(19) United States
(12) Patent Application Publication
(10) Pub. No.: US 2010/0109159 A1
(43) Pub. Date: May 6, 2010

(54) BUMPED CHIP WITH DISPLACEMENT OF GOLD BUMPS

(76) Inventors: Chih-Wen HO, Kaohsiung (TW); Yung-Fa Huang, Kaohsiung (TW); Ming-Kuo Wei, Kaohsiung (TW); Po-Chien Lee, Kaohsiung (TW)

Correspondence Address: Muncy, Geissler, Olds & Lowe, PLLC, P.O. BOX 1364, FAIRFAX, VA, 22038-1364, US

(21) Appl. No.: 12/582,285

(22) Filed: Oct. 20, 2009

(30) Foreign Application Priority Data
Nov. 3, 2008 (TW) 097142422

(51) Int. Cl. H01L 23/498

(52) U.S. Cl. 257/737; 257/E23.068

(57) ABSTRACT

A bumped chip is revealed, including a chip, a UBM layer, an Ag bump, and a creeping-resist layer. The chip has a bonding pad and a passivation layer covering one surface of the chip and exposing the bonding pad. The UBM layer is disposed on the bonding pad and covers the passivation layer at the peripheries of the opening. The Ag bump is disposed on the UBM layer to form as a pillar bump having a top surface and a pillar sidewall. The creeping-resist layer is formed at least on the pillar sidewall to fully encapsulate the Ag bump. Therefore, the disclosed bumped chip will have no Ag-creeping due to exerting stresses nor changing of joint heights under high temperature environment to meet the bumping requirements of lead-free, high reliability, and lower cost.

### FIELD OF THE INVENTION

The present invention relates to semiconductor devices, and more particularly to bumped chips.

### BACKGROUND OF THE INVENTION

Flip-chip bonding (FC) technology and inner lead bonding (ILB) technology are to dispose a plurality of conductive bumps or extruded electrodes on the bonding pads on the active surface of a chip, then the bumped chip is flipped and bonded to a substrate or the inner leads of a substrate are thermally compressed to the bumped chip to achieve electrical connections. Comparing to the conventional wire-bonding electrical connections, flip chip technology and inner lead bonding technology have shorter electrical paths between a chip and a substrate especially for high I/O density products with better signal qualities with higher operation frequencies.

Since the bonding of conductive bumps between a chip and a substrate are point-to-point electrical connections, any substrate warpage induced by thermal stresses will cause the bumps to break leading to electrical failure between a chip and a substrate.

Currently flip chip technologies can be classified into two major categories, one is solder balls reflowed from solder bumps where solder bumps can not meet the lead-free requirements, moreover, solder bumps can not maintain suitable jointed heights between a chip and a substrate under high temperature reflow leading to bridging between adjacent solder bumps which is not suitable for fine-pitch flip chip applications. The other is bonding by non-reflowable pillar bumps such as Au (gold) bumps where Au bumps are electrically connected to a substrate through thermal compressions or by anisotropic conductive paste. Even though the reliability of Au bumps is good without bridging issues between adjacent Au bumps, however, the material cost of Au bumps is very high, therefore, substitute bumps are needed.

Recently, low-cost non-reflowable bumps are developed to replace Au bumps where all of or bottom portions of the conductive bumps are made of copper (Cu) which is a harder material than Au and is called copper bumps. Since copper bumps are harder with less flexibility, the stresses exerted on copper bumps directly transfer to the interfaces between the copper bumps and the metal pads of a chip leading to breakage at the bottom of copper bumps or even damages to a chip. The breakage at the bottom of copper bumps become even worse due to the coplanarity of a plurality of copper bumps which can not accurately control during fabrication processes and due to the jointed heights between a chip and a substrate which can not easily maintain due to substrate warpage. Furthermore, copper bumps are easily oxidized where a nitrogen environment is needed during copper bump fabrication and chip bonding processes or an anti-oxidation protection is required after bump formation. The cost of copper bumps can not effectively be reduced due to more processing limitations.

### SUMMARY OF THE INVENTION

The main purpose of the present invention is to provide a bumped chip with the similar Au bump functions and properties to replace the conventional Au bumps and to excel the known copper bumps without bottom breakage issues to meet lead-free, high reliability, and low cost requirements.

The second purpose of the present invention is to provide a bumped chip to achieve high-density bump design and arrangement to increase bonding strengths between a chip and a substrate to enhance signal qualities for high frequency applications.

According to the present invention, a bumped chip is revealed, primarily comprising a chip, an under-bump metallurgy (UBM) layer, an Ag (silver) bump, and a creeping-resist layer. A chip has a bonding pad and a passivation layer where the passivation layer covers one surface of the chip and has an opening exposing the bonding pad. The UBM layer is disposed on the bonding pad to cover the passivation layer around the opening. The Ag bump is disposed on the UBM layer to form as a pillar bump having a top surface and a pillar sidewall. The creeping-resist layer is formed on the top surface and/or on the pillar sidewall to completely encapsulate the Ag bump. Preferably, an annular indentation is formed at the rim of the UBM layer by the formation of the creeping-resist layer in a manner that the creeping-resist layer is not in direct contact with the passivation layer. In one of the embodiment, the creeping-resist layer only encapsulates the pillar sidewall of the Ag bump. The Ag bump may be directly disposed on the bonding pad. In another embodiment, the Ag bump may be encapsulated by multiple creeping-resist layers to reduce the creeping effects.

The bumped chip according to the present invention has the following advantages and functions:

1. In the pillar bump applications, Ag (silver) bumps are chosen to replace Au (gold) bumps or Cu (copper) bumps with the similar hardness of Au bumps and without bottom breakage of copper bumps to meet lead-free, high reliability, and low cost bumping requirements. Furthermore, the creeping effects of Ag bumps under stresses can be reduced with the creeping-resist layer disposed on the surfaces of the Ag bump.

2. Through Ag bumps fully encapsulated with the creeping-resist layer, the joint heights and deformation under stress of the Ag bumps will not change under high temperature environment.

3. Through further extending the creeping-resist layer disposed on the surfaces of Ag bumps to the rim of UBM layer to fully encapsulate the Ag bumps, the breakage of the creeping-resist layer at the bottom of the pillar sidewalls of Ag bumps can be avoided after flip chip assembly to enhance the functions of the creeping-resist layer and to effectively reduce creeping effects of Ag bumps.

### DESCRIPTION OF THE DRAWINGS

FIG. 1 is a partial cross-sectional view of a bumped chip according to the first embodiment of the present invention.

FIGS. 2A to 2F are cross-sectional views of components of a bumped chip during fabrication processes according to the first embodiment of the present invention.

FIGS. 3A to 3C are three-dimensional views of different Ag bump designs for the bumped chip according to the first embodiment of the present invention.

FIG. 4 is a cross-sectional view of a semiconductor flip-chip device having the bumped chip in according to the first embodiment of the present invention.

FIG. 5 is a cross-sectional view of another semiconductor flip-chip device having the bumped chip according to the first embodiment of the present invention.

FIG. 6 is a partial cross-sectional view of another bumped chip according to the second embodiment of the present invention.

FIG. 7 is a partial cross-sectional view of another bumped chip according to the third embodiment of the present invention.

FIG. 8 is a partial cross-sectional view of another bumped chip according to the fourth embodiment of the present invention.

FIG. 9 is a partial cross-sectional view of another bumped chip according to the fifth embodiment of the present invention.

### DETAILED DESCRIPTION OF THE INVENTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

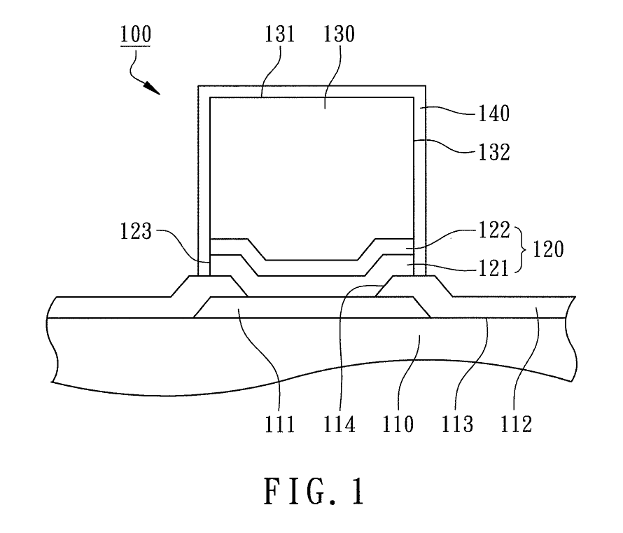

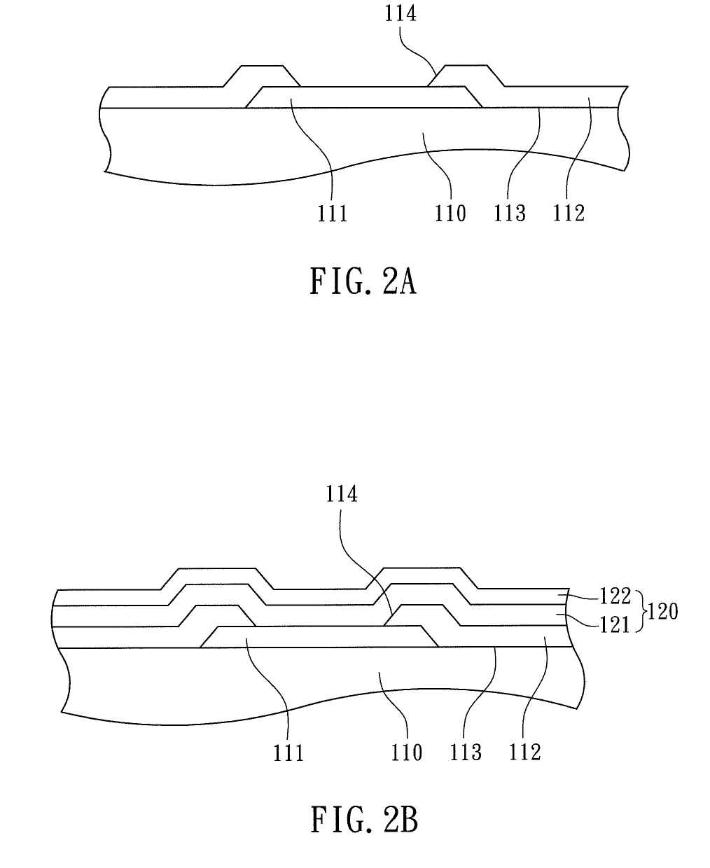

According to the first embodiment of the present invention, a bumped chip 100 is illustrated in FIG. 1 for a cross-sectional view and from FIG. 2A to FIG. 2F for cross-sectional views of its components during fabrication processes.

As shown in FIG. 1, the bumped chip 100 primarily comprises a chip 110, an UBM layer 120, an Ag bump 130, and a creeping-resist layer 140. The chip 110 has a bonding pad 111 and a passivation layer 112 where the passivation layer 112 covers one surface 113 of the chip 110 with an opening 114 to expose the bonding pad 111. When the bonding pads 111 are plural, some or all of the openings 114 are also plural correspondingly. The chip 100 is made of semiconductor materials such as Si (silicon) or III-V semiconductors (such as GaAs) where the surface 113 is the active surface of the chip 110 with IC components formed on it such as micro-controllers, micro-processors, memories, logics, ASIC, LCD drivers, or combinations of the above IC components. The bonding pad 111 is made of metals such as Aluminum, copper, and its alloys as the external signal terminals of the chip 110. The passivation layer 112 is a surface coating material made of dielectric materials such as PI (Polyimide), BCB (Benzo-Cyclo-Butene), PSG (Phosphosilicate glass), Silicon oxide, Silicon Nitride or Nitride. The passivation layer 112 is formed by CVD (Chemical Vapor Deposition) to protect the IC components on the surface 113 and to planarize the surface 113. In the present embodiment, the dimension of the opening 114 is slightly smaller than the one of the corresponding bonding pad 111 so that the passivation layer 112 may partially cover the peripheries of the bonding pad 111.

As shown in FIG. 1, the UMB layer 120 is disposed on the bonding pads 111 in a manner to cover the passivation layer 112 around the opening 114. The UBM layer 120 is made of metals and is electrically connected to the bonding pad 111. To be more specific, the UBM layer 120 includes an adhesion layer 121 and a wetting layer 122 for enhancing the bonding strength between the Ag bump 130 and the bonding pad 111. To be described in detail, the adhesion layer 121 is directly bonded to the bonding pad 111 where the wetting layer 122 is directly disposed on the adhesion layer 121. The adhesion layer 121 provides good adhesions to the bonding pad 111 and to the passivation layer 112 and barriers for preventing metal diffusion where the adhesion layer 121 is made of Ti or TiW. The wetting layer 122 provides good wetting capabilities for the Ag bump 130, which is made of gold or other metals. The adhesion layer 121 and the wetting layer 122 may be formed by sputtering. Normally, the dimension of the UMB layer 120 is greater than the dimension of the opening 114 of the passivation layer 112 extending to the corresponding peripheries of the opening 114 of the passivation layer 112 to form an exposed rim 123 on the passivation layer 112.

As shown in FIG. 1 again, the Ag bump 130 is disposed on the UBM layer 120 to form as a pillar bump having a top surface 131 and a pillar sidewall 132. Normally, an angular boundary is formed between the top surface 131 and the pillar sidewall 132 of the Ag bump 130, such as 90°. The height of the Ag bump 130 can be greater than the diameter or the width of the bottom of the Ag bump 130 where the heights of the Ag bump range from 5 um (micrometer) to 25 um. To be described in detail, the Ag bump 130 is made of pure silver or silver alloy having silver content not less than 80 wt % (weight percentage). Therefore, the Ag bump 130 has similar hardness of the conventional Au bump but softer than copper bump with good conductivity and elongation properties, moreover, the cost of Ag bump 130 is relatively lower than the cost of conventional Au bumps. Furthermore, the Ag bump 130 can meet the lead-free requirements without degrading the functions and qualities of Au bumps to replace conventional Au bumps and without bottom breakage issues of conventional copper bumps.

As shown in FIG. 1 again, the creeping-resist layer 140 is formed on the top surface 131 and on the pillar sidewall 132 to completely encapsulate the Ag bump 130 where the thickness of the creeping-resist layer 140 ranges from 0.03 um to 3 um. In a more specific embodiment, the thickness of the creeping-resist layer 140 is 1 um where the creeping resist layer 140 is just a thin coating film when compared to the height of the Ag bump 130 (from 5 um to 25 um). The creeping-resist layer 140 is made of Au or Au alloys to have the characteristics of anti-oxidation and high conductivity. Accordingly, the hardness of the creep-resist layer 140 is not greater than the hardness of the Ag bump 130 without affecting or changing the strengths of the whole bump.

Generally speaking, metals will not change nor deform with exerted stresses under the elasticity limitations in room temperature. However, when exposed to high stress and high temperature environments, metals will gradually change and deform relative to time even with exerted stresses far under the elasticity limitations where this phenomenon is called “creeping”. Since Ag bumps are much easier to creep than Au bumps and copper bumps, therefore, in the present invention, the encapsulation of the creeping-resist layer 140 disposed on the surface of the Ag bump 130 is specially required, especially the fully encapsulation of the pillar sidewall 132 of the Ag bump 130 to avoid gradually creeping of the Ag bump 130 under exerted stresses to prevent the sideward deformation of the Ag bump 130 to maintain the joint height and effective bonding without electrical short between adjacent Ag bumps 130.

Preferably, as shown in FIG. 1, the UBM layer 120 has the rim 123 without covering by the Ag bump 130 where the creeping-resist layer 140 may further extend to cover the above mentioned rim 123 of the UBM layer 120 so that the creeping-resist layer 140 is fully encapsulated the Ag bump 130 and the UBM layer 120 without any surfaces exposed to the atmosphere. In the general embodiment, the Ag bump 130 is fully encapsulated by the creeping-resist layer 140 so that the breakage of the creeping-resist layer 140 at the bottom of the pillar sidewall 132 of the Ag bump 130 is avoided to enhance the function of the creeping-resist layer 140 to effectively reduce the creeping of the Ag bump 130.

As shown from FIG. 2A to FIG. 2F, the fabrication processes of the bumped chip 100 is further described in detail to manifest the effectiveness of the present invention.

As shown in FIG. 2A, the first step is to provide a chip 110 where a plurality of chips 110 are formed on a wafer. The chip 110 has the bonding pad 111 and the passivation layer 112 covering one surface 113 of the chip 110 with an opening 114 to expose the bonding pad 111.

As shown in FIG. 2B, the second step is to form the UBM layer 120 on top of the bonding pad 111. The UBM layer 120 is not yet patterned to completely cover the passivation layer 112. The adhesion layer 121 and the wetting layer 122 of the UBM layer 120 are formed by known deposition technologies of semiconductor processes such as sputtering. Accordingly, the UBM layer 120 in this step can cover the exposed surface of the bonding pad 111 and the whole surface of the passivation layer 112. The wetting layer 122 can be configured for bump plating

As shown in FIG. 2C, the third step is to form a patterned mask such as a photoresist 10 formed on top of the UBM layer 120. Generally speaking, the photoresist 10 can be chosen from liquid type photoresist or dry-film type photoresist where the photoresist 10 goes through photolithographic processes such as exposure and development to form a plurality of openings 11 to expose the corresponding position of the UBM layer 120 on the bonding pad 111. The opening 11 defines the formation area for the Ag bumps 130 and the UBM layer 120. In the present embodiment, the opening 11 is slightly greater than the corresponding bonding pad 111. However, in other embodiment, the opening 11 can be formed outside the bonding pads to match the design requirement of redistribution traces (RDL) for electrical connections.

As shown in FIG. 2D, the fourth step is to form the Ag bump 130 inside the opening 11 by electroplating through the wetting layer 122 where the Ag bump 130 is electrically and mechanically connected to the UBM layer 120.

As shown in FIG. 2E, the fifth step is to strip the photoresist 10 where the photoresist 10 is stripped to expose the unpatterned UBM layer 120 except the portion of the UBM layer 120 under the Ag bump 130.

As shown in FIG. 2F, the sixth step is to etch the UBM layer 120 including the adhesion layer 121 and the wetting layer 122 except the portion of the UBM layer 120 under the Ag bump 130. Therein, the final dimension of the UBM layer 120 is defined by the coverage of the Ag bump 130 to form the rim 123 of the UBM layer 120. In one embodiment, the pillar sidewall 132 of the Ag bump 130 is aligned to the rim 123 of the UBM layer 120 on the same vertical plane.

As shown in FIG. 1 again, the seventh step is to form a creeping-resist layer 140 to fully encapsulate the Ag bump 130 including the top surface 131 and the pillar sidewall 132 without any exposed surfaces. By the full encapsulation of the creeping-resist layer 140 on the Ag bump 130, the creeping of the Ag bump 130 can be avoided.

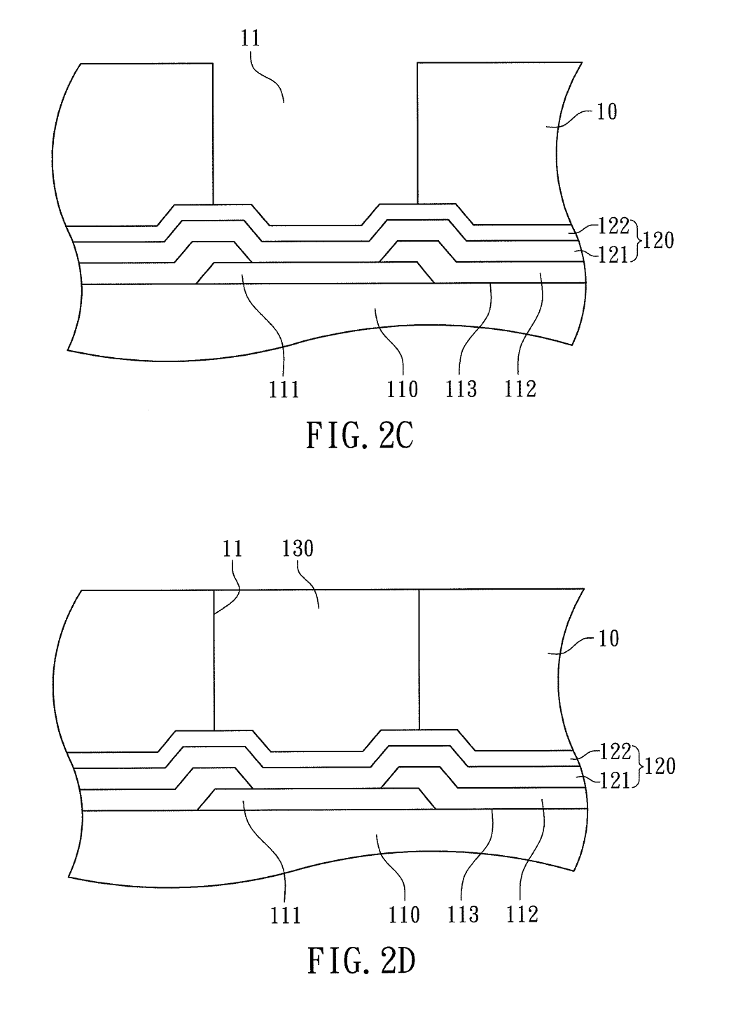

To be more specific, as shown from FIG. 3A to FIG. 3C, the shapes of the Ag bump 130 can be a cube, a cylinder, or a cuboid in various embodiments. But without any limitations, the shape of the Ag bump 130 can be a polyhedron. Each kind of the Ag bumps 130, 130′, and 130″ has a top surface 131, 131′, and 131″ and a pillar sidewall 132, 132′, and 132″ respectively. Preferably, the Ag bump 130 is tetragonal, i.e., where the sidewalls are perpendicular to the top surface and to the bottom surface with good structural integrity to enhance the creeping-resist function. There is an angular boundary formed between the top surface 131, 131′, 131″ and the corresponding pillar sidewall 132, 132′, 132″.

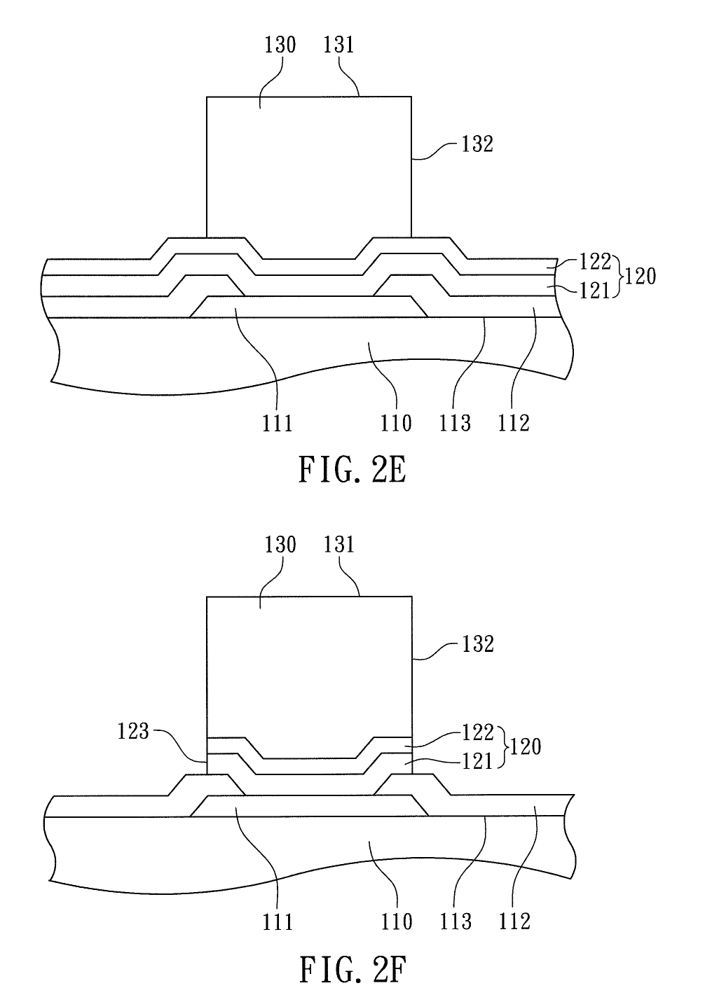

FIG. 4 is the cross-sectional view of the bumped chip 100 implemented in a flip-chip semiconductor device where the bumped chip 100 is flip-chip connected to a substrate 20 to achieve shorter electrical paths to enhance chip performance.

As shown in FIG. 4, the flip-chip semiconductor device primarily comprises a bumped chip 100 and a substrate 20 where one surface 21 of the substrate 20 has a plurality of connecting pads 22. The substrate 22 can be a glass substrate or a high-density multi-layer printed circuit board with conductive circuitry formed inside. The Ag bump 130 is electrically and mechanically connected to the connecting pad 22 of the substrate 20 through the creeping-resist layer 140, i.e., the creeping-resist layer 140 is soldered and bonded to the connecting pad 22 to electrically connect the chip 110 to the substrate 20 through ultrasonic bonding or thermal compression. Even under high temperature environment, the Ag bump 130 will not experience creeping caused by exerted stresses because the pillar sidewall 132 of the Ag bump 130 is encapsulated and protected by the creeping-resist layer 140. Preferably, the substrate 20 may be a glass substrate so that after the bumped chip 100 is flip-chip bonded on the substrate 20, the breakage of the creeping-resist layer 140 can be observed from the other surface opposing to the surface 21 of the substrate 20 by visual or optical inspection.

To be in more detail, as shown in FIG. 4 and FIG. 1, the flip-chip semiconductor device further comprises an underfill 30 formed in the gap between the bumped chip 100 and the substrate 20 to encapsulate the creeping-resist layer 140 disposed on the pillar sidewall 132 of the Ag bump 130. The underfill 30 can be applied by dispension along one or two edges of the chip 110 to fully encapsulate the gap through the capillary action. Then, the underfill 30 is cured to protect the Ag bump 130 and the creeping-resist layer 140.

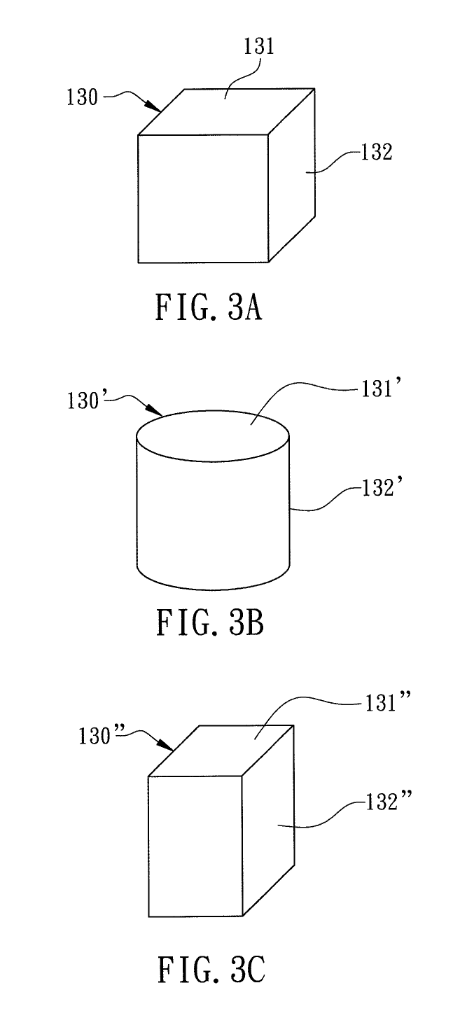

As shown in FIG. 5, a cross-sectional view of a bumped chip implemented in another semiconductor flip chip device is revealed.

In the present embodiment, the bumped chip 100 is electrically connected to the substrate 20 through an anisotropic conductive paste (ACP) 40 where the ACP is formed on top of the substrate 20 by printing or attaching first, then the bumped chip 100 is flip-chip bonded to the substrate 20. The ACP 40 comprises a plurality of conductive particles 41 where some of the conductive particles 41 are directly contacted to the creeping-resist layer 140 and to the connecting pads 22 to achieve vertical electrical connections without soldering to avoid metal diffusion issues. The conductive particles 41 have the same diameters ranging from 2 um to 3 um where the conductive particles 41 are evenly distributed in the ACP 40 to achieve vertical anisotropic conduction. The creeping-resist layer 140 offers a fixing function for the connected conductive particles 41 by partially embedding the particles 41 in the creeping-resist layer 140.

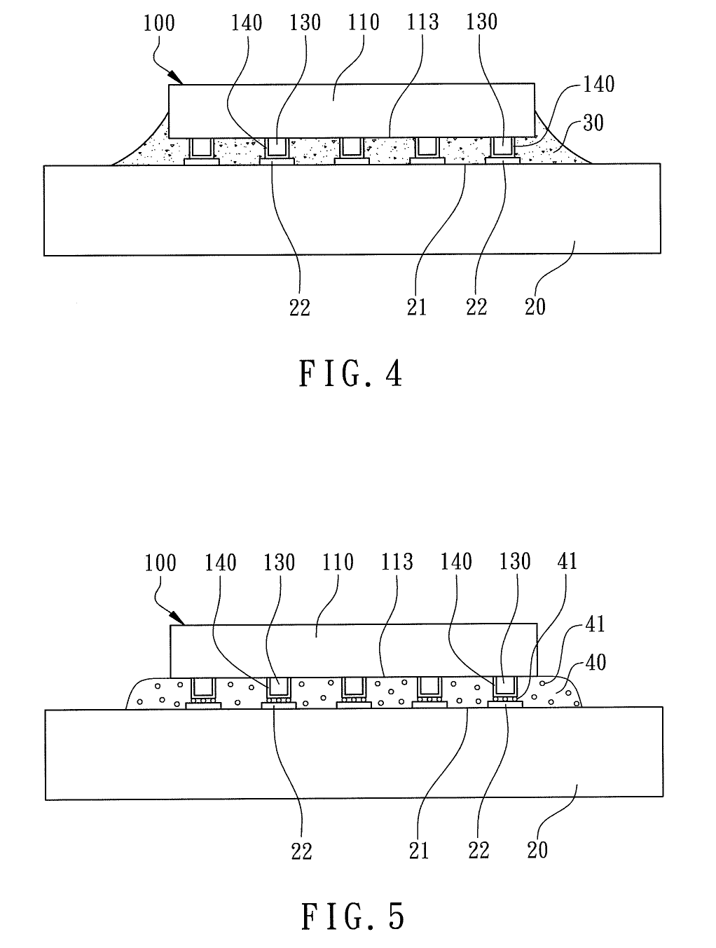

According to the second embodiment of the present invention, another bumped chip 200 is illustrated in FIG. 6 for a partial cross-sectional view. The bumped chip 200 primarily comprises a chip 110, an Ag bump 130, and a creeping-resist layer 140 where the same designated numbers are used to describe the major components which are the same as the first embodiment.

In the present embodiment, the bumped chip 200 can eliminate the UBM layer to reduce the fabrication cost. The Ag bump 130 is directly formed on top of the bonding pad 111 where the creeping-resist layer 140 is still fully encapsulated the pillar sidewall 132 of the Ag bump 130. The bumped chip 200 further comprises a soldering material 250 disposed on the top surface 131 of the Ag bump 130 so that the creeping-resist layer 140 may or may not cover the top surface 131 of the Ag bump 130 where the maximum thickness of the soldering material 250 is greater than the thickness of the creeping-resist layer 140. During flip-chip assembly processes, the soldering material 250 will be melted and electrically and mechanically connected to the connecting pads of a substrate through the high-temperature thermal compression processes. Normally the soldering material 250 prefers lead-free solder paste such as Sn (96.5%)—Ag (3%)—Cu (0.5%) where the wetting solderability is available when the temperature is above 217° C. with the maximum reflow temperature of 245° C. Moreover, the melting points of the Ag bump 130 and the creeping-resist layer 140 must be higher than the above reflowing temperature.

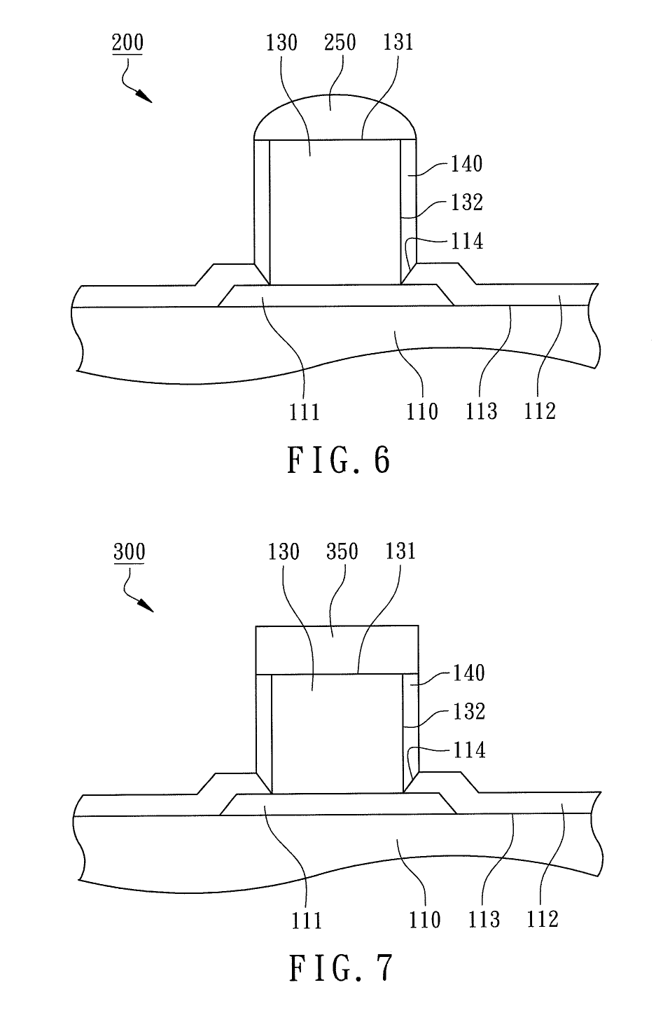

According to the third embodiment of the present invention, another bumped chip 300 is illustrated in FIG. 7 for a partial cross-sectional view. The bumped chip 300 primarily comprises a chip 110, an Ag bump 130, and a creeping-resist layer 140 where the same designated numbers are used to describe the major components which are the same as the first embodiment.

In the present embodiment, the creeping-resist layer 140 is fully encapsulated the pillar sidewall 132 of the Ag bump 130 where the bumped chip 300 further comprises a bonding cap 350 disposed on the top surface 131 of the Ag bump 130. The thickness of the bonding cap 350 is greater than the thickness of the creeping-resist layer 140 where Au (gold) can be used as the bonding cap 350 with thicknesses ranging from 2 um to 6 um which is far thicker than the thickness of the creeping-resist layer 140 so that the oxidation issues of the Ag bump 130 can be avoided because the thickness of the creeping-resist layer on the top surface 131 is insufficient for probing which will be punched through during probing processes to expose the Ag bump 130 leading to oxidation of Ag bump 130.

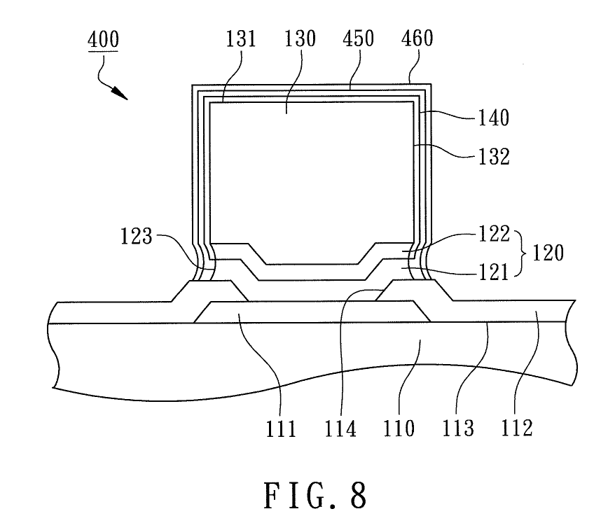

According to the fifth embodiment of the present invention, another bumped chip 400 is illustrated in FIG. 8 for a partial cross-sectional view. The bumped chip 400 primarily comprises a chip 110, a UBM layer 120, an Ag bump 130, and a first creeping-resist layer 140 where the same designated numbers are used to describe the major components which are the same as the first embodiment.

In the present embodiment, the silver content of the Ag bump 130 is not less than 99 wt % where high purity of Ag is suitable for electroplating processes to easily achieve homogeneous states without hardness variation of Ag bumps due to defeats caused by uneven distribution of Ag. Moreover, the first creeping-resist layer 140 forms not only on the pillar sidewall 132 but also on the top surface 131 to ensure no exposed surfaces of the Ag bump 130 where the material of the first creeping-resist layer 140 is chosen from the group consisting of Au, Pd, Cu, and Ni. Preferably, the first creeping-resist layer 140 is chosen from either replacement Au or reduction Au so that the time to form the creeping-resist layer 140 under 1 um thickness (from several tens to several hundreds Å) is shorter where the lateral dimensions of the bump will not increase and the joint height will not change nor reduce with the benefits of lower costs and thinner thicknesses. Moreover, the hardness of the first creeping-resist layer 140 can not be higher nor similar to the hardness of the Ag bump 130 so that the bump strengths will not be altered. Moreover, the bump strength of the Ag bump 130 will not be changed nor affected even with the thickness of the first creeping-resist layer 140 increased or decreased. The UBM layer 120 has a rim 123 without covering by the Ag bump 130 where the rim 123 is sunk into the pillar sidewall 132 of the Ag bump 130 so that the first creeping-resist layer 140 will not fully cover the rim 123. Therefore, an annular indentation is formed on the rim 123 of the UBM layer 120 through partially covering of the first creeping-resist layer 140 so that the creeping-resist layer 140 is not in direct contact with the passivation layer 112.

Preferably, as shown in FIG. 8 again, the Ag bump 130 can be encapsulated by a plurality of creeping-resist layers 140, 450 and 460 to enhance the creeping-resist function. The bumped chip 400 further comprises a second creeping-resist layer 450 to encapsulate the first creeping-resist layer 140 and to fill the annular indentation where the first creeping-resist layer 140 and the second creeping-resist layer 450 will fully encapsulate the Ag bump 130 and the UBM layer 120. The material of the second creeping-resist layer 450 is chosen from the group consisting of Au, Pd, Cu, and Ni which can be the same as or different from the material of the first creeping-resist layer 140. When the combination of replacement Au and reduction Au is chosen, the materials of the first creeping-resist layer 140 and the second creeping-resist layer 450 can be the same. When a double-layer creeping-resist layer is chosen, the combination of the first creeping-resist layer 140 and the second creeping-resist layer 450 can be chosen from the group consisting of Pd/Au, Cu/Au, Ni/Au, Au/Au, and Ni/Pd and be formed by replacement reactions or chemical plating. To be more specific, when a triple-layer creeping-resist layer is chosen, the bumped chip 400 further comprises a third creeping-resist layer 460 to encapsulate the second creeping-resist layer 450 where the material of the third creeping-resist layer 460 can be chosen from either Au or Pd which is different from the second creeping-resist layer 450. The combination of the first creeping-resist layer 140, the second creeping-resist layer 450, and the third creeping-resist layer 460 can be chosen from the group consisting of Ni/Pd/Au, Au/Ni/Au, Cu/Ni/Au, and Cu/Ni/Pd. Therefore, the bumped chip 400 can have a multiple-layer creeping-resist layer 140, 450, and 460 to ensure fully encapsulation of the Ag bump 130 and to enhance the creeping-resist function.

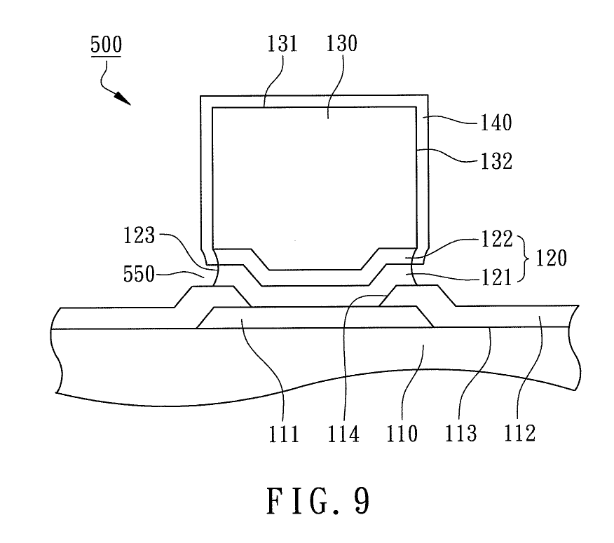

According to the fifth embodiment of the present invention, another bumped chip 500 is illustrated in FIG. 9 for a partial cross-sectional view. The bumped chip 500 primarily comprises a chip 110, a UBM layer 120, an Ag bump 130, and a creeping-resist layer 140 where the same designated numbers are used to describe the major components which are the same as the first embodiment.

In the present embodiment, the creeping-resist layer 140 is formed on and fully encapsulated the top surface 131 and the pillar sidewall 132 of the Ag bump 130. Preferably, the creeping-resist layer 140 on the pillar sidewall 132 further extends to part of the rim 123 of the UBM layer 120 in a manner to form an annular indentation 550 to avoid the direct contact of the creeping-resist layer 140 to the passivation layer 112. Furthermore, as shown in FIG. 9 again, the width of the annular indentation 550 can not be greater than the thickness of the UBM layer 120 to ensure the creeping-resist layer 140 fully encapsulating the Ag bump 130 so that the Ag bump 130 isn't exposed to the atmosphere. In the present embodiment, since the Ag bump 130 is fully encapsulated, the breakage of the creeping-resist layer 140 at the bottom of the pillar sidewall 132 of the Ag bump 130 can be avoided after flip chip assembly to enhance the function of creeping-resist and to effectively reduce the creeping of the Ag bump 130. To be described in detail, the creeping-resist layer 140 can partially cover the rim 123 of the UBM layer 120 such as the creeping-resist layer 140 covers the rim of the wetting layer 122 with the rim of the adhesion layer 121 exposed so that the creeping-resist layer 140 is not in direct contact with the passivation layer 112 of the chip 110 to achieve high-density bump arrangement, to increase the bonding strengths between the chip 110 and the substrate, and to enhance the signal quality at high frequency applications. Furthermore, the annular indentation 550 serves as a buffering zone to control the creeping-resist layer 140 for fully encapsulation of the Ag bump 130 without direct contact to the passivation layer 112 to reduce electrical short between adjacent bumps and to prevent the deformation of the Ag bump 130 affecting the chip 110 such as the breakage from the bottom of the Ag bumps 130 leading to electrical quality issues.

In conclusion, the bumped chip of the present invention implements creeping-resist layers to encapsulate the Ag bump to avoid creeping of the Ag bump to maintain the joint height under high temperature environment to meet lead-free requirements with higher reliability and lower bumping cost. Therefore, the Ag bump can be implemented as pillar bumps in semiconductor chips.

The above description of embodiments of this invention is intended to be illustrative but not limited. Other embodiments of this invention will be obvious to those skilled in the art in view of the above disclosure which still will be covered by and within the scope of the present invention even with any modifications, equivalent variations, and adaptations.

What is claimed is:

1. A bumped chip comprising:
a chip having a bonding pad and a passivation layer covering one surface of the chip with an opening to expose the bonding pad;
a UBM layer disposed on the bonding pad to cover the passivation layer around the opening;
an Ag bump disposed on the UBM layer to form as a pillar bump having a top surface and a pillar sidewall; and
a creeping-resist layer formed on the top surface and the pillar sidewall to fully encapsulate the Ag bump.

2. The bumped chip as claimed in claim 1, wherein the material of the Ag bump is chosen from the group consisting of pure silver and silver alloy with silver content not less than 80 wt %.

3. The bumped chip as claimed in claim 1, wherein the UBM layer includes an adhesion layer and a wetting layer, the adhesion layer is disposed on the bonding pad and the wetting layer is disposed on the adhesion layer.

4. The bumped chip as claimed in claim 1, wherein the material of the creeping-resist layer includes gold having the characteristics of anti-oxidation and high conductivity.

5. The bumped chip as claimed in claim 1, wherein the UBM layer has a rim not covered by the Ag bump, wherein the creeping-resist layer further extends to and covers the rim of the UBM layer.

6. The bumped chip as claimed in claim 1, wherein the height of the Ag bump ranges from 5 um to 25 um and the thickness of the creeping-resist layer ranges from 0.03 um to 3 um.

7. The bumped chip as claimed in claim 1, wherein an angular boundary is formed between the top surface and the pillar sidewall of the Ag bump.

8. The bumped chip as claimed in claim 1, wherein the hardness of the creeping-resist layer is not greater than the hardness of the Ag bump.

9. The bumped chip as claimed in claim 1, wherein an annular indentation is formed at a rim of the UBM layer by the formation of the creeping-resist layer in a manner that the creeping-resist layer is not in direct contact with the passivation layer.

10. A bumped chip comprising:
a chip having a bonding pad and a passivation layer covering one surface of the chip with an opening to expose the bonding pad;
an Ag bump disposed above the bonding pad to form as a pillar bump having a top surface and a pillar sidewall; and
a creeping-resist layer fully covering the pillar sidewall of the Ag bump.

11. The bumped chip as claimed in claim 10, further comprising a solder material disposed on the top surface of the Ag bump, wherein the maximum thickness of the solder material is greater than the thickness of the creeping-resist layer.

12. The bumped chip as claimed in claim 10, further comprising a bonding cap disposed above the Ag bump and having a thickness greater than the thickness of the creeping-resist layer.

13. The bumped chip as claimed in claim 10, wherein the material of the Ag bump is chosen from the group consisting of pure silver and silver alloy with silver content not less than 80 wt %.

14. The bumped chip as claimed in claim 10, wherein the material of the creeping-resist layer includes gold having the characteristics of anti-oxidation and high conductivity.

15. The bumped chip as claimed in claim 10, wherein the height of the Ag bump ranges from 5 um to 25 um and the thickness of the creeping-resist layer ranges from 0.03 um to 3 um.

16. The bumped chip as claimed in claim 10, wherein an angular boundary is formed between the top surface and the pillar sidewall of the Ag bump.

17. The bumped chip as claimed in claim 10, wherein the hardness of the creeping-resist layer is not greater than the hardness of the Ag bump.

18. The bumped chip as claimed in claim 10, further comprising a UBM layer disposed between the bonding pad and the Ag bump to covering the passivation layer around the opening, wherein the UBM layer has a rim not covered by the Ag bump, wherein the creeping-resist layer further extends to and covers the rim of the UBM layer.

19. The bumped chip as claimed in claim 18, wherein an annular indentation is formed at the rim of the UBM layer by the formation of the creeping-resist layer in a manner that the creeping-resist layer is not in direct contact with the passivation layer.

20. A bumped chip comprising:
a chip having a bonding pad and a passivation layer covering one surface of the chip with an opening to expose the bonding pad;
a UBM layer disposed on the bonding pad to cover the passivation layer around the opening;
an Ag bump disposed on the UBM layer to form as a pillar bump having a top surface, a pillar sidewall and a silver content not less than 99 wt %; and
a first creeping-resist layer formed on the pillar sidewall, wherein the material of the first creeping-resist layer is chosen from the group consisting of Au, Pd, Cu, and Ni.

21. The bumped chip as claimed in claim 20, wherein the first creeping-resist layer is further formed on the top surface to fully encapsulate the Ag bump.

22. The bumped chip as claimed in claim 20, wherein the first creeping-resist layer has an exposed surface, and the material of the first creeping-resist layer is chosen from the group consisting of Au and Pd.

23. The bumped chip as claimed in claim 20, further comprising a second creeping-resist layer covering the first creeping-resist layer, and the material of the second creeping-resist layer is chosen from the group consisting of Au, Pd, Cu, and Ni.

24. The bumped chip as claimed in claim 23, further comprising a third creeping-resist layer covering the second creeping-resist layer, the material of the third creeping-resist layer is chosen from the group consisting of Au and Pd and is not the same as the material of the second creeping-resist layer.

25. The bumped chip as claimed in claim 20, wherein the UBM layer has a rim not covered by the Ag bump, wherein the first creeping-resist layer further extends to and covers the rim of the UBM layer.

26. The bumped chip as claimed in claim 25, wherein an annular indentation is formed at the rim of the UBM layer by the formation of the first creeping-resist layer in a manner that the first creeping-resist layer is not in direct contact with the passivation layer.

27. The bumped chip as claimed in claim 20, wherein an angular boundary is formed between the top surface and the pillar sidewall of the Ag bump.

28. The bumped chip as claimed in claim 20, wherein the first creeping-resist layer is chosen from the group consisting of replacement Au and reduction Au.

29. The bumped chip as claimed in claim 25, wherein the rim of the UBM layer is relatively recessed with respect to the pillar sidewall of the Ag bump.
